(19) United States
(12) Patent Application Publication
(10) Pub. No.: US 2016/0164523 A1
(43) Pub. Date: Jun. 9, 2016

(54) INTERFACE SUPPLY CIRCUIT

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: ZHEN-SHENG WANG, Wuhan (CN); CHUN-SHENG CHEN, New Taipei (TW)

(21) Appl. No.: 14/615,703

(22) Filed: Feb. 6, 2015

(30) Foreign Application Priority Data
Dec. 8, 2014 (CN) 201410739507.9

(51) Int. Cl. H03K 19/0185

(52) U.S. Cl. CPC H03K 19/018507

(57) ABSTRACT

An interface supply circuit includes a power supply unit, a first control circuit coupled to the power supply unit, a second control coupled to the circuit power supply unit, and an output unit. The output unit is coupled to the first control circuit and the second control circuit. The first control circuit is configured to output a first voltage via the output unit when a system is in a normal state. The second control circuit is configured to output a second voltage via the output unit when the system is in a stand-by state.

### CROSS-REFERENCE TO RELATED APPLICATIONS

This application claims priority to Chinese Patent Application No. 201410739507.9 filed on Dec. 8, 2014, the contents of which are incorporated by reference herein.

### FIELD

The subject matter herein generally relates to a power supply circuit.

### BACKGROUND

A working state of a system comprises a normal state (S0 state), a stand-by state, and a shutdown state (S5 state), and the stand-by state comprises a sleep state (S3 state) and a dormant state (S4 state). An interface supply circuit may be used to output different voltages when the system is in different working states.

### BRIEF DESCRIPTION OF THE DRAWINGS

Implementations of the present technology will now be described, by way of example only, with reference to the attached figures.

FIG. 1 is a block diagram of one embodiment of an interface supply circuit and an interface.

FIG. 2 is a circuit diagram of the interface supply circuit and the interface of FIG. 1.

FIG. 3 is a table of one embodiment of values of a plurality of voltage signals of the interface supply circuit of FIG. 2.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising,” when utilized, means “including, but not necessarily limited to”; it specifically indicates open-ended inclusion or membership in the so-described combination, group, series, and the like.

The present disclosure is described in relation to an interface supply circuit outputting a plurality of voltages.

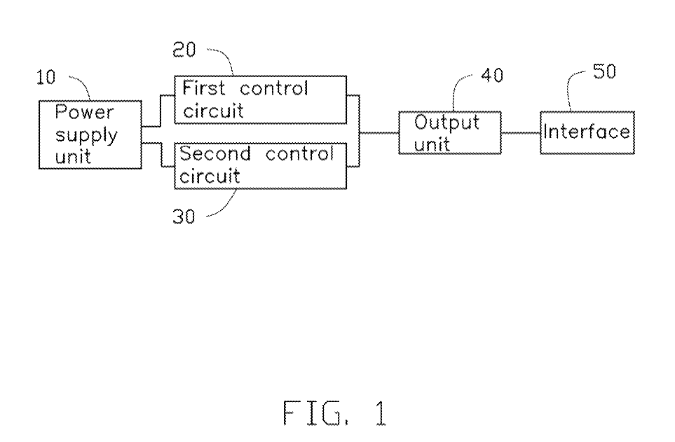

FIG. 1 illustrates an embodiment of an interface supply circuit. The interface supply circuit is used in an electronic whiteboard. The interface supply circuit comprises a power supply unit 10, a first control circuit 20 coupled to the power supply unit 10, a second control circuit 30 coupled to the power supply unit 10, and an output unit 40. The power supply unit 10 is configured to provide a first power supply 11, a second power supply 12, a third power supply 13, and a fourth power supply 14. The first power supply 11 is configured to provide a first voltage signal. The second power supply 12 is configured to provide a second voltage signal. The third power supply 13 is configured to provide a third voltage signal. The fourth power supply 14 is configured to provide a fourth voltage signal. The output unit 40 is configured to couple to an interface 50. In one embodiment, the interface 50 is a USB interface.

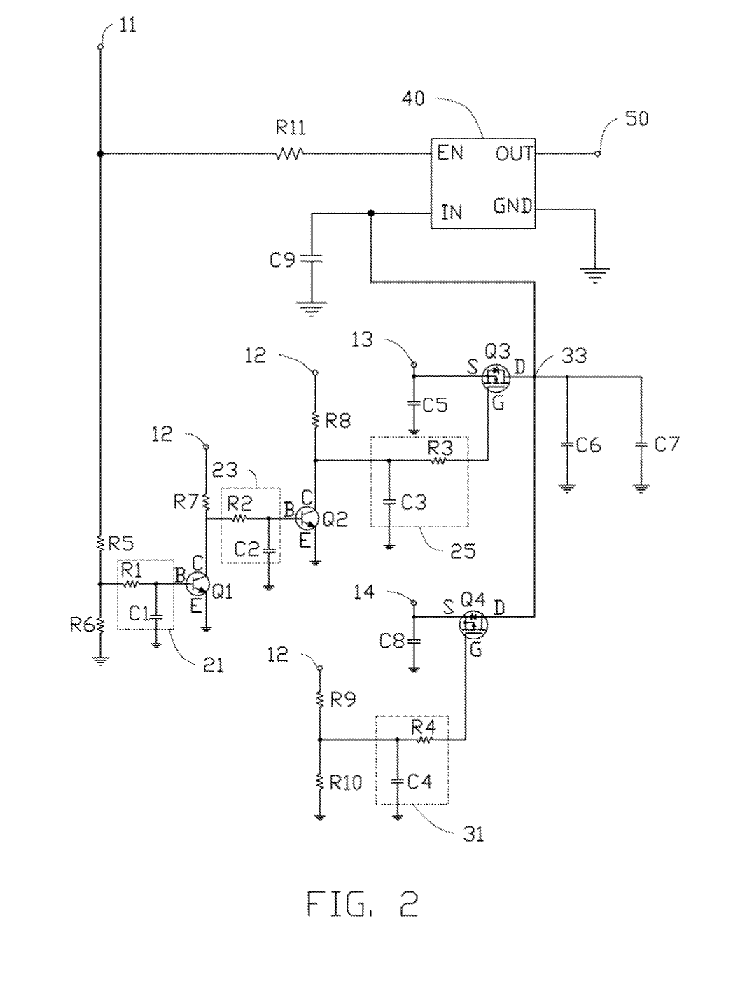

FIG. 2 illustrates that the first control circuit 20 comprises a first delay circuit 21, a first field effect transistor (FET) Q1, a second delay circuit 23, a second FET Q2, a third delay circuit 25, and a third FET Q3. The second control circuit 30 comprises a fourth delay circuit 31 and a fourth FET Q4. Each of the first FET Q1 and the second FET Q2 comprises an input terminal B, a first output terminal C, and a second output terminal E. Each of the third FET and the fourth FET Q4 comprises a control terminal G, a first connecting terminal S, and a second connecting terminal D.

The output unit 40 comprises an input pin IN, an output pin OUT, an enabling pin EN, and a ground pin GND.

In one embodiment, each of the first delay circuit 21, the second delay circuit 23, the third delay circuit 25 and the fourth delay circuit 31 is a RC circuit. The first delay circuit 21 comprises a first resistor R1 and a first capacitor C1. The second delay circuit 23 comprises a second resistor R2 and a second capacitor C2. The third delay circuit 25 comprises a third resistor R3 and a third capacitor C3. The fourth delay circuit 31 comprises a fourth resistor R4 and a fourth capacitor C4.

The first power supply 11 is coupled to one end of the first resistor R1 via a fifth resistor R5 and is coupled to one end of a sixth resistor R6 via the fifth resistor R5. The other end of the sixth resistor R6 is grounded. The other end of the first resistor R1 is grounded via the first capacitor C1 and is coupled to the input terminal B of the first FET Q1. The first output terminal C of the first FET Q1 is coupled to the second power supply 12 via a seventh resistor R7. The first output terminal C of first FET Q1 is coupled to one end of the second resistor R2. The other end of the second resistor R2 is grounded via the second capacitor C2 and is coupled to the input terminal B of the second FET Q2. The second output terminal E of the first FET Q1 is grounded. The second output terminal E of the second FET Q2 is grounded. The first output terminal C of the second FET Q2 is coupled to the second power supply 12 via an eighth resistor R8. The first output terminal C of the second FET Q2 is coupled to one end of the third resistor R3. The first output terminal C of the second FET Q2 is grounded via the third capacitor C3. The other end of the third resistor R3 is coupled to the control terminal G of the third FET Q3. The first connecting terminal S of the third FET Q3 is coupled to the third power supply 13. The first connecting terminal S of the third FET Q3 is grounded via a fifth capacitor C5. The second connecting terminal D of the third FET Q3 is coupled to a node 33. The node 33 is grounded via a sixth capacitor C6 and is grounded via a seventh capacitor C7. The node 33 is coupled to the second connecting terminal D of the fourth FET Q4. The first connecting terminal S of the fourth FET Q4 is coupled to the fourth power supply 14. The first connecting terminal S of the fourth FET Q4 is grounded via an eighth capacitor C8. The control terminal G of the fourth FET Q4 is coupled to one end of the fourth resistor R4. The other end of the fourth resistor R4 is grounded via the fourth capacitor C4, is coupled to the second power supply 12 via a ninth resistor R9, and is grounded via a tenth resistor R10.

In one embodiment, the node 33 is configured to provide a fifth voltage signal.

The enabling pin EN of the output unit 40 is coupled to the first power supply 11 via a eleventh resistor R11. The output pin OUT of the output unit 40 is coupled to the interface 50. The input pin IN of the output unit 40 is coupled to the node 33. The input pin IN of the output unit 40 is grounded via a ninth capacitor C9. The ground pin GND of the output unit 40 is grounded.

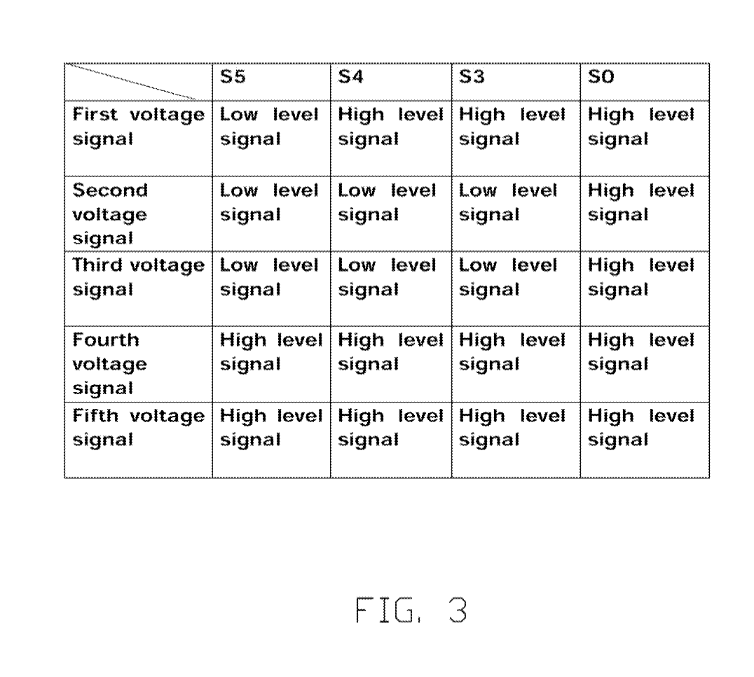

FIG. 3 illustrates that the voltage signals are different level values when a system of the electronic whiteboard is in different working states. The working state of the system comprises a normal state (S0 state), a stand-by state, and a shutdown state (S5 state), and the stand-by state comprises a sleep state (S3 state) and a dormant state (S4 state). When the system is in the S5 state, each of the first voltage signal, the second voltage signal, and the third voltage signal is a low level signal, and each of the fourth voltage signal and the fifth voltage signal is a high level signal. When the system is in the S4 state, each of the second voltage signal and the third voltage signal is a low level signal, each of the first voltage signal, the fourth voltage signal, and the fifth voltage signal is a high level signal. When the system is in the S3 state, each of the second voltage signal and the third voltage signal is a low level signal, each of the first voltage signal, the fourth voltage signal, and the fifth voltage signal is a high level signal. When the system is in the S0 state, each of the first voltage signal, the second voltage signal, the third voltage signal, the fourth voltage signal, and the fifth voltage signal is a high level signal.

A working principle of the interface supply circuit is as follows. When the system is in the S5 state, the first voltage signal is a low level signal, the output unit 40 does not supply power to the interface 50 after receiving the low first voltage signal. When the system is in the S4 and S3 state, each of the second voltage signal and the third voltage signal is a low level signal, the first voltage signal, the fourth voltage signal, and the fifth voltage signal is a high level signal, the first FET Q1 is switched on, the second FET Q2 is switched off, the third FET Q3 is switched off, and the fourth FET Q4 is switched on. The fourth power supply 14 connects to the input terminal IN of the output unit 40 via the fourth FET Q4. The enabling pin EN of the output unit 40 outputs a first voltage to supply power to the interface 50 after receiving the high first voltage signal. When the system is in the S0 state, each of the first voltage signal, the second voltage signal, the third voltage signal, the fourth voltage signal, and the fifth voltage signal is a high level signal, the fourth FET Q4 is switched off, the first FET Q1 is switched on, the second FET Q2 is switched on, and the third FET Q3 is switched on. The third power supply 13 connects to the input terminal IN of the output unit 40 via the third FET Q3. The output pin OUT of the output unit 40 outputs a second voltage to supply power to the interface 50 after the enabling pin EN of the output unit 40 receives the high first voltage signal.

In one embodiment, each of the first FET Q1 and the second FET Q2 is a triode, each input terminal B is a base B, each first output terminal C is a collector C, each second output terminal E is an emitter E, the third FET Q3 is a n-channel FET, the fourth FET Q4 is a p-channel FET, each control terminal G is a gate terminal G, each first connecting terminal S is a source terminal S, and each second connecting terminal is a drain terminal D.

In the interface supply circuit, when the system is in the S4 and S3 state, the second control circuit 30 outputs the first voltage to supply power to the interface 50 via the output unit 40. When the system is in the S0 state, the first control circuit 20 outputs the second voltage to supply power to the interface 50 via the output unit 40.

It is to be understood that even though numerous characteristics and advantages have been set forth in the foregoing description of embodiments, together with details of the structures and functions of the embodiments, the disclosure is illustrative only and changes may be made in detail, including in the matters of shape, size, and arrangement of parts within the principles of the disclosure to the full extent indicated by the broad general meaning of the terms in which the appended claims are expressed.

What is claimed is:

1. An interface supply circuit for an electronic whiteboard comprising:
a power supply unit;
a first control circuit coupled to the power supply unit;
a second control circuit coupled to the circuit power supply unit; and
an output unit;
wherein the output unit is coupled to the first control circuit and the second control circuit;
wherein the first control circuit is configured to be switched on and output a first voltage via the output unit when a system of the electronic whiteboard is in a first working state; and
wherein the second control circuit is configured to be switched on and output a second voltage via the output unit when the system is in a second working state.

2. The interface supply circuit of claim 1, wherein the first control circuit comprises a first field effect transistor (FET) and a second FET, the first FET is coupled to the power supply unit, the second FET is coupled to the output unit, the first FET is switched on when the system is in the first working state, the second FET is switched on after the first FET is switched on, and the second FET outputs the first voltage via the output unit after being switched on.

3. The interface supply circuit of claim 2, wherein the first control circuit further comprises a third FET, the third FET is coupled to the power supply unit and the first FET, the third FET is switched on when the system is in the first working state, and the first FET is switched on after the third FET is switched on.

4. The interface supply circuit of claim 3, wherein the power supply unit is configured to provide a first voltage signal and a second voltage signal, the first voltage signal is configured to be sent to the first FET and the second FET, and the second voltage signal is configured to be sent to the second FET.

5. The interface supply circuit of claim 4, wherein the second voltage signal is a low level signal when the system is in the second working state.

6. The interface supply circuit of claim 4, wherein the power supply unit is configured to provide a third voltage signal, the third voltage signal is configured to be sent to the third FET, and the first voltage signal is configured to be sent to the third FET.

7. The interface supply circuit of claim 6, wherein the third voltage signal is a high level signal.

8. The interface supply circuit of claim 3, wherein the second control circuit comprises a fourth FET, the power supply unit is configured to provide a first voltage signal and a second voltage signal, the first voltage signal is configured to be sent to the fourth FET, and the second voltage signal is configured to be sent to the fourth FET.

9. The interface supply circuit of claim 8, wherein the first voltage signal is a low level signal when the system is in the second working state.

10. The interface supply circuit of claim 1, wherein the first working state is a normal state and the second working state is in a stand-by state.

11. An interface supply circuit for an electronic whiteboard comprising:
a power supply unit;
a first control circuit coupled to the power supply unit;
a second control coupled to the circuit power supply unit; and
an output unit;
wherein the output unit is coupled to the first control circuit and the second control circuit;
wherein the first control circuit is configured to be switched on and output a first voltage via the output unit when a system of the electronic whiteboard is in a normal state; and
wherein the second control circuit is configured to be switched on and output a second voltage via the output unit when the system is in a stand-by state.

12. The interface supply circuit of claim 11, wherein the first control circuit comprises a first field effect transistor (FET) and a second FET, the first FET is coupled to the power supply unit, the second FET is coupled to the output unit, the first FET is switched on when the system is in the normal state, the second FET is switched on after the first FET is switched on, and the second FET outputs the first voltage via the output unit after being switched on.

13. The interface supply circuit of claim 12, wherein the first control circuit further comprises a third FET, the third FET is coupled to the power supply unit and the first FET, the third FET is switched on when the system is in the normal state, and the first FET is switched on after the third FET is switched on.

14. The interface supply circuit of claim 13, wherein the power supply unit is configured to provide a first voltage signal and a second voltage signal, the first voltage signal is configured to be sent to the first FET and the second FET via a first resistor, and the second voltage signal is configured to be sent to the second FET.

15. The interface supply circuit of claim 14, wherein the second voltage signal is a low level signal when the system is in the stand-by state.

16. The interface supply circuit of claim 14, wherein the power supply unit is configured to provide a third voltage signal, the third voltage signal is configured to be sent to the third FET via a second resistor, and the first voltage signal is configured to be sent to the third FET via the first resistor.

17. The interface supply circuit of claim 16, wherein the third voltage signal is a high level signal.

18. The interface supply circuit of claim 13, wherein the second control circuit comprises a fourth FET, the power supply unit is configured to provide a first voltage signal and a second voltage signal, the first voltage signal is configured to be sent to the fourth FET via a resistor, and the second voltage signal is configured to be sent to the fourth FET.

19. The interface supply circuit of claim 18, wherein the second voltage signal is a high level signal.

20. The interface supply circuit of claim 11, wherein the output unit comprises an input pin and an enabling pin, the enabling pin of the output unit is coupled to a first power supply, and the input pin of the output unit is grounded via a capacitor.
